(19) United States
(12) Patent Application Publication
(10) Pub. No.: US 2025/0265184 A1
(43) Pub. Date: Aug. 21, 2025

(54) MULTI-PLANE WORD LINES

(71) Applicant: Microchip Technology Incorporated, Chandler, AZ (US)

(72) Inventors: Nian Niles YANG, Mountain View, CA (US); Pitamber SHUKLA, San Jose, CA (US); Murthy HARI, San Jose, CA (US)

(21) Appl. No.: 18/807,975

(22) Filed: Aug. 17, 2024

Related U.S. Application Data
(60) Provisional application No. 63/555,398, filed on Feb. 19, 2024.

(51) Int. Cl. G06F 12/02; G11C 16/04; G11C 16/08; G11C 16/10; G11C 16/26

(52) U.S. Cl. CPC G06F 12/0238; G11C 16/08; G06F 2212/251; G11C 16/0483; G11C 16/10; G11C 16/26

(57) ABSTRACT

In some implementations, a controller of a storage device may configure the storage device with a multi-plane word line that includes a first word line of a first plane having a first index, and a second word line of a second plane having a second index that is offset from the first index. The controller may perform a write operation or read operation on the multi-plane word line. In this way, the multi-plane word line may include word lines that are at different indices at different planes and thereby reduce high error rates for particular multi-plane word lines that may otherwise be caused by physical imperfections shared by word lines at the same indices at different planes.

### CROSS-REFERENCE TO RELATED APPLICATION

This Patent Application claims priority to Provisional Patent Application No. 63/555,398, filed on Feb. 19, 2024, and entitled “MULTI-PLANE WORD LINES.” The disclosure of the prior Application is considered part of and is incorporated by reference into this Patent Application.

### FIELD

The present disclosure generally relates to multi-plane word lines of a storage device. In particular, the multi-plane word line may be configured such that the multi-plane word line includes a word line of a first plane at a first word line index and a word line of a second plane at a second word line index that is offset from the first word line index.

### BACKGROUND

A non-volatile memory device may include a memory device that may store and retain data without external power supply. One example of a non-volatile memory device is a negative-and (NAND) flash memory device. The non-volatile memory device (also referred to as a “storage device”) may be configured with word lines on respective planes of the memory device. The word lines may include bits from multiple bit lines (e.g., with the bit lines organized in a dimension that is perpendicular to the word lines). Word lines from multiple planes (e.g., with the multiple planes organized in a dimension that is perpendicular to the word lines) may be combined to form a multi-plane word line.

### SUMMARY

In some implementations, a method performed by a controller of a storage device includes configuring the storage device with a multi-plane word line that comprises: a first word line of a first plane having a first index, and a second word line of a second plane having a second index that is offset from the first index; and performing a write operation or read operation on the multi-plane word line.

In some implementations, a system comprising: a controller, of a non-volatile memory device, to: configure a storage device with a multi-plane word line that comprises: a first word line of a first plane having a first index, and a second word line of a second plane having a second index that is offset from the first index; and perform a write operation on the multi-plane word line.

In some implementations, a computer program product comprising: one or more computer readable storage media, and program instructions collectively stored on the one or more computer readable storage media, the program instructions comprising: program instructions to configure a storage device with a multi-plane word line that comprises: a first word line of a first plane having a first index, and a second word line of a second plane having a second index that is offset from the first index; and program instructions to perform a write operation or a read operation on the multi-plane word line.

### BRIEF DESCRIPTION OF THE DRAWINGS

FIGS. 1A-1D are diagrams of examples of multi-plane word lines, as described herein.

FIG. 2 is a diagram of an example of using multi-plane word lines, described herein.

FIG. 3 is a diagram of example components of one or more devices of FIGS. 1A-2.

FIG. 4 is a flowchart of an example process associated with using multi-plane word lines described herein.

### DETAILED DESCRIPTION

The following detailed description of example implementations refers to the accompanying drawings. The same reference numbers in different drawings may identify the same or similar elements.

A storage device may include a solid-state drive (SSD). In some examples, the storage device, such as an SSD, may include a plurality of non-volatile memory devices, such as NAND flash memory devices, without limitation. A non-volatile memory device may store data that is accessible via a controller. The controller may include one or more of an application specific integrated circuit (ASIC) or firmware.

Data storage on a storage device (e.g., a non-volatile memory device) may be subject to errors. For example, data stored on the storage device may be stored in physical components of transistors or other binary storage units. To store a bit of data (using a write operation) within the storage device, the controller may apply a voltage to a transistor that changes a state of the transistor to be read as a 1 or a 0 when using a read operation to apply a read voltage. The application of voltages in a read operation or a write operation may not be successful, which may cause errors in the data.

Additionally, over time and after numerous program/erase operations and write operations, storage on the storage device may degrade based at least in part on degradation of physical components of the transistors or connected devices. For example, insulating materials, channel materials, gates, or conductive layers may interact to degrade barriers used to form current paths and voltage storage within the storage device.

Data stored on the storage device may be organized into word lines that traverse multiple bit lines (e.g., with one bit per bit line, for example). Based at least in part on manufacturing processes of the storage device, if a bit of the word line has an error caused by a physical imperfection of the storage device (e.g., along a bit line), other bits of the word line may have an increased likelihood of having an error caused by the physical imperfection of the storage device.

The word line may have an index within a plane of a channel of the storage device. Similar to the bits of the word line having an increased likelihood of errors based at least in part on a first bit having an error caused by a physical imperfection of the storage device, word lines having a same index on another plane may have an increased likelihood of errors based at least in part on the first bit having the error caused by the physical imperfection of the storage device.

In some storage devices, data may be further organized into multi-plane word lines (e.g., super word lines) that include word lines having a same index on multiple planes of the storage device (e.g., with the multiple planes associated with a same channel or die of the storage device). However, based at least in part on word lines having a same index on other planes having an increased likelihood of errors based at least in part on the first bit having an error caused by a physical imperfection of the storage device, the multi-plane word line may have too many errors to be corrected by an error correction operation (e.g., an XOR operation or a low-density parity check (LDPC), among other examples). In this way, the physical imperfections may cause a failure with respect to storing data on the multi-plane word line.

In some aspects, a storage device (e.g., an SSD) will fail eventually over time. Failures on the storage device may be induced by storage media of the storage device (e.g., NAND dies). For example, defects such as word line-to-word line or word line-to-memory hole shorts may cause a failure of the storage device.

RAID5 or RAID6 parity (e.g., using XOR schemes) may be used in data loss recovery for data loss caused by various reasons, such as the above-mentioned defects associated with word lines. However, these parity techniques may recover errors to a certain degree (e.g., no more than 2 or 3 failures), over which the parity will corrupt and XOR will not be able to rebuild the original data (e.g., recover the data).

Unrecoverable errors become more and more likely as a quantity of storage media (e.g., NAND dies) in the storage device increases (e.g., the quantity may be than 1000). Also, the word line errors may increase in association with NAND scaling where more layers of the word lines are being built as well (e.g., from 64 to 96 to 128 to 160 to 232 or greater than 300, among other examples). The likelihood of failure also increases on a per storage media (e.g., per NAND die) level.

In some aspects described herein, a controller may configure a storage device with multi-plane word lines that have a first set of indices on a first plane and a second set of indices on a second plane. For example, a particular word line may have a first index on a first plane and may have a second index on a second plane that is offset from the first index. In this way, for a multi-plane word line, a physical imperfection that may cause an error between a word line at the first index with an adjacent word line (e.g., a first word line of the multi-plane word line) may not carry over to a second word line at the second index based at least in part on the second index being offset from the first index.

In some aspects, a logical block address (LBA) to physical block address (PBA) conversion may be performed at a controller level of the storage device. The controller may determine the PBA for a write operation or a read operation. For the address bits (e.g., NAND address bits) that control the word line of a particular storage medium or plane, the controller may insert an offset equal to given number, such as “d100.” For the edge word line, the controller may use a different offset in an opposite direction, so that when this storage medium or plane is programmed or read, instead of WL(n) (e.g., associated with the LBA), the controller is may actually read a word line at WL(n+z), where z can be positive or negative. The value of z may be controlled by the storage device or the controller. The multiplane word line may include word lines at WL(n), and WL(n+z) from different storage media or planes. Offsetting may reduce a possibility of simultaneous WL defects related to WL(n) across the multiple storage media or planes. For example, if there is a physically induced failure at WL(n), WL(n+z) is less likely to experience the same failure as it is offset from WL(n), and the XOR parity has a better chance to recover the data loss.

The technique may be referred to as an “out of order” programming scheme on the storage media. In some aspects, the technique may mitigate effects of being “out of order” by following a “tiered” principle for a programming schedule (e.g., a NAND programming schedule), as long as the value of “z” is chosen properly.

Based at least in part on the first index of the first word line of the multi-plane word line being offset from the second index of the second word line of the multi-plane word line, the multi-plane word line may have fewer errors than a multi-plane word line having word lines all having a same index. Based at least in part on having fewer errors, an error correction operation may have an improved likelihood of success in correcting data stored via the multi-plane word line and may have improved reliability. In this way, the storage device may have improved success in storing and reading data. For example, the storage device may reduce defective parts per million (DPPM), reduce uncorrectable block error rate (UBER), or reduce annual failure rate (AFR), among other examples.

In some examples, by offsetting with a value as small as z=1, the defects induced by storage medium failure can be halved without changing a technique for XOR parity recovery.

In some aspects, having the offset may reduce a probability of defects for a large-scale storage device (e.g., SSD), where the errors would otherwise be more likely to occur. In some aspects, the offset may be managed by a storage medium (e.g., NAND) itself or the storage device controller (e.g., ASIC controller). In some aspects, the offset may be configured or used in-flight as the storage device or storage medium ages. In this way, using the offset is a solution that can be applied at both the storage device or at the storage medium level without extra implementation cost in a factory or manufacturing site. Additionally, using the offset may improve user experience.

In some aspects, an XOR scheme or other decoding technique can vary based at least in part on implementation choices. However, using the offset within word lines can add value to improved decoding that is independent of which XOR scheme or decoding technique is implemented. For example, this technique may be used with peripheral component interface express (PCIe) non-volatile memory express (NVMe), and compute express link (CXL) protocol.

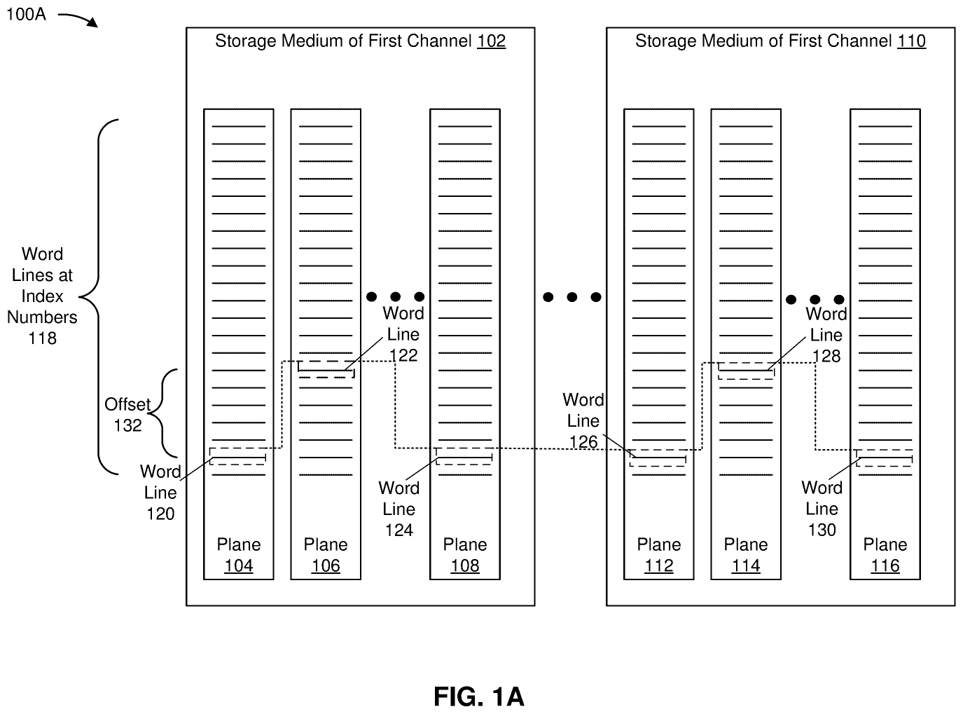

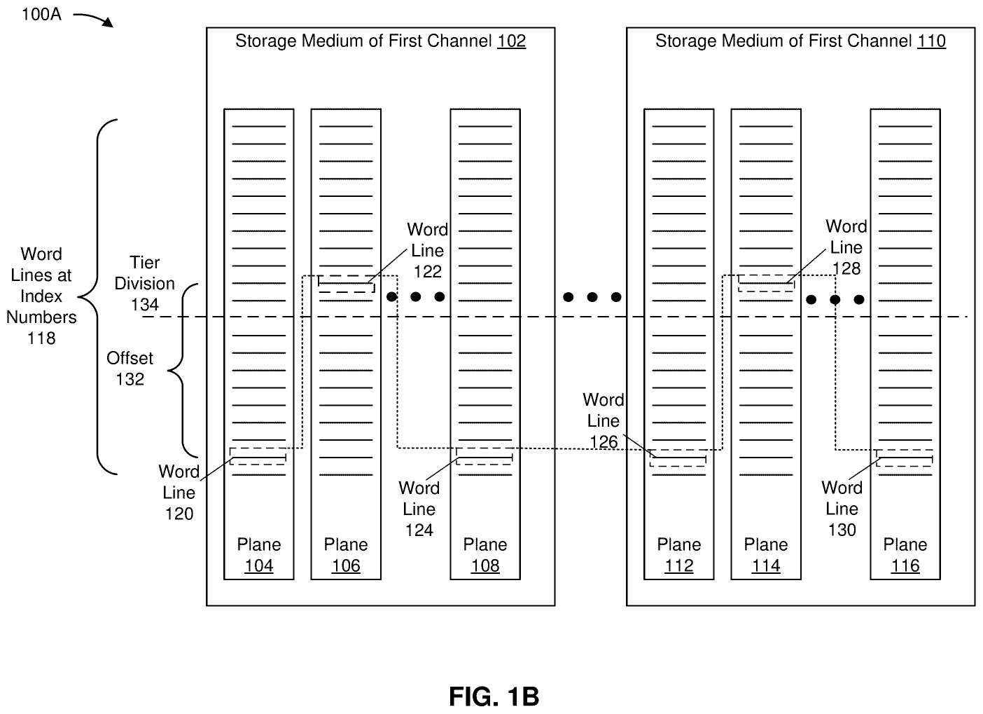

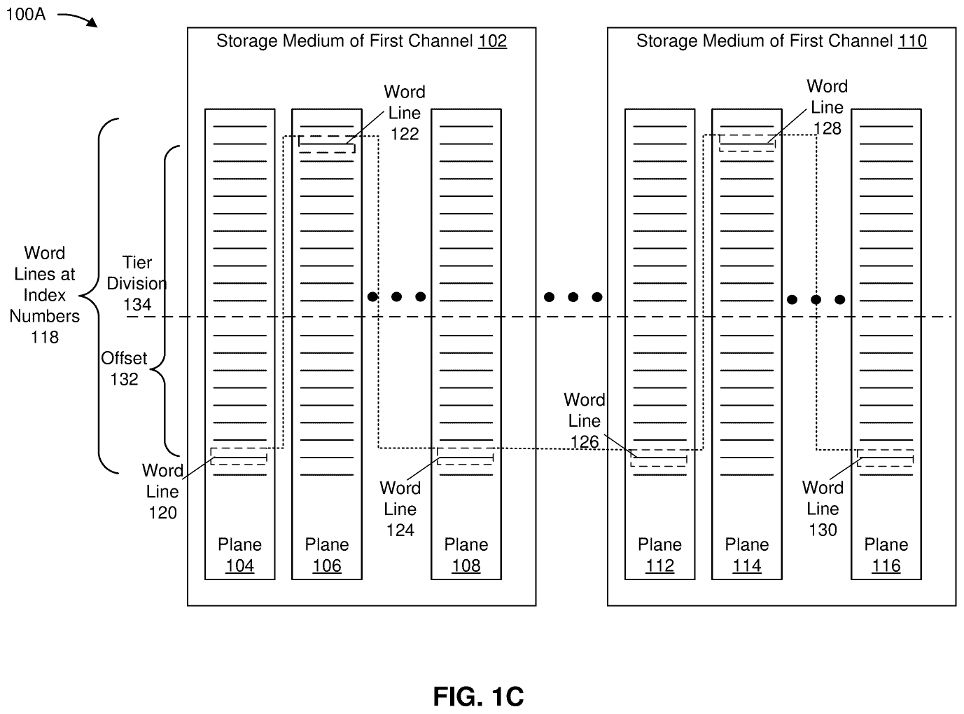

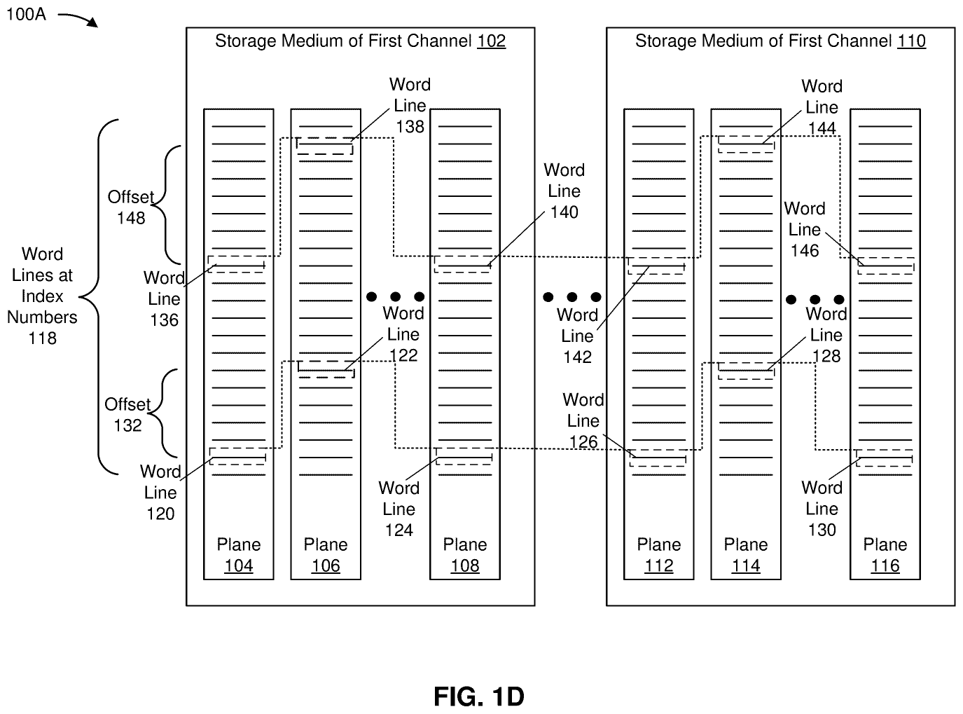

FIGS. 1A-1D are diagrams of examples of multi-plane word lines, as described herein. The multi-plane word lines of FIGS. 1A-1D may be configured within storage medium, which may include multiple channels (e.g., each associated with a different storage medium or sets of which associated with a different storage medium, among other examples). Although shown as including word lines from multiple channels, the multi-plane word lines may include word lines from only one channel or from only one storage medium. Additionally, offsets shown and a quantity of word lines are provided as examples without limitation.

As shown in FIG. 1A, a storage medium of a first channel 102 (referred to as storage medium 102) may include planes 104, 106, 108 and a storage medium of a second channel 110 (referred to as storage medium 110) may include planes 112, 114, 116. The planes 104, 106, 108, 112, 114, 116 include word lines at index numbers 118. For example, each plane may include a set of word line index numbers (e.g., a same set of word line index numbers).

In some storage devices not shown, a multi-plane word line may include word lines on multiple planes at the same word line index. However, based at least in part on a manufacturing process of forming bit lines of the planes crossing multiple word lines (e.g., all of the word lines at each of the index numbers), with multiple word lines being formed in layers simultaneously, adjacent word line indices have increased likelihoods of having errors across multiple planes.

As shown in FIG. 1A, a multi-plane word line may include word lines 120, 122, 124, 126, 128, 130. Consecutive word lines (e.g., 120 and 122) may be located at word line indices having an offset 132. As shown in FIG. 1A, the offset 132 between consecutive word lines 120 and 122 may be the same in magnitude as the offset 132 between consecutive word lines 122 and 124. In this way, word line 120 and word line 124 may be located at a same index. The storage medium 102 may include word lines on additional planes, with the word lines of the multi-plane word line alternating between two or more index values having a same offset 132.

Similarly, the offset 132 between consecutive word lines 126 and 128 may be the same in magnitude as the offset 132 between consecutive word lines 122 and 124. Alternatively, the offset 132 associated with storage medium 102 may be different from the offset 132 associated with storage medium 110. Additionally, or alternatively, a last word line of storage medium 102 may be offset from a first word line of storage medium 110.

As shown in FIG. 1B, the word lines 120, 122, 124, 126, 128, 130 may alternate between tiers of word line indices. For example, the planes 104, 106, 108, 112, 114, 116 may include a first tier and a second tier that are divided by a tier division 134. In this way, the offset 132 may be sufficiently large to separate the word line 120 and the word line 122 enough to be in different tiers. For example, the offset may be equal to a number of word line indices within a tier. In this way, the offset 132 may force consecutive word lines into different tiers. For example, a first word line (e.g., word line 120) may be associated with a first tier of word lines and a second word line (e.g., word line 122) may be associated with a second tier of word lines. If the offset is equal to the number of word line indices within a tier, word line 120 may have a same word line index within the first tier as the word line 122 has within the second tier (e.g., the second word line from the bottom edge of each tier).

As shown in FIG. 1C, as in FIG. 1B, the offset 132 may separate the word line 120 and the word line 122 into different tiers. In contrast to FIG. 1B, FIG. 1C shows word line 122 having an index value that is equal to a difference between a highest value of the range of indices and the first value. For example, if the word line index numbers range from 0 to 99, the word line 120 may have an index value of 1 and the word line 122 may have an index value of 98 (99 is the highest value and 1 is the index value of the word line 120, so 99−1=98). Alternatively, the index of the word line 122 within the second tier may be counted in a direction that is opposite from the index of the word line 120 within the first tier. For example, the word line 120 may have an index that is counted from the bottom up (e.g., toward the second tier that includes the word line 122) and the word line 122 may have an index that is counted from the top down (e.g., toward the first tier that includes the word line 120). For example, the word line 120 may have an index value of 1 within a lower tier (e.g., below the tier division 134) that counts from the bottom up (e.g., towards the tier division 134) and the word line 122 may also have an index value of 1 within a higher tier (e.g., above the tier division 134) the counts from the top down (e.g., towards the tier division 134). As an example, when we have two tiers, the word lines selected are the one in plane 106 the 2nd from the top, and the one in plane 104 the 2nd from the bottom. They can be operated simultaneously per NAND technology. Similarly, word line 122 and word line 124 may have a same word line index counted in opposite directions or the word line 124 may be at an index that is equal to a difference between a highest value of the range of indices and the first value.

As shown in FIG. 1D, an additional word line (e.g., a second word line) is also stored on the storage medium 102 and the storage medium 110. As shown in FIG. 1D, the additional multi-plane word line may include word lines 136, 138, 140, 142, 144, 146. Consecutive word lines of the additional multi-plane word line may be separated by indices equal to an offset 148. In some aspects, the offset 148 may be equal to the offset 132. Alternatively, the offset 148 may be different from the offset 132.

In some aspects, the offset 132 or 148 may be the same between each of the consecutive word lines. In some aspects, the offset 132 or 148 may be different between some or each of the consecutive word lines. In some aspects, a first set of consecutive word lines may not be offset within the first set of consecutive word lines, and the first set of consecutive word lines may be offset from a second set of consecutive word lines. For example, a first pair of word lines may be at a same index number and a second pair of word lines may be at a second index number that is offset from the first pair of word lines.

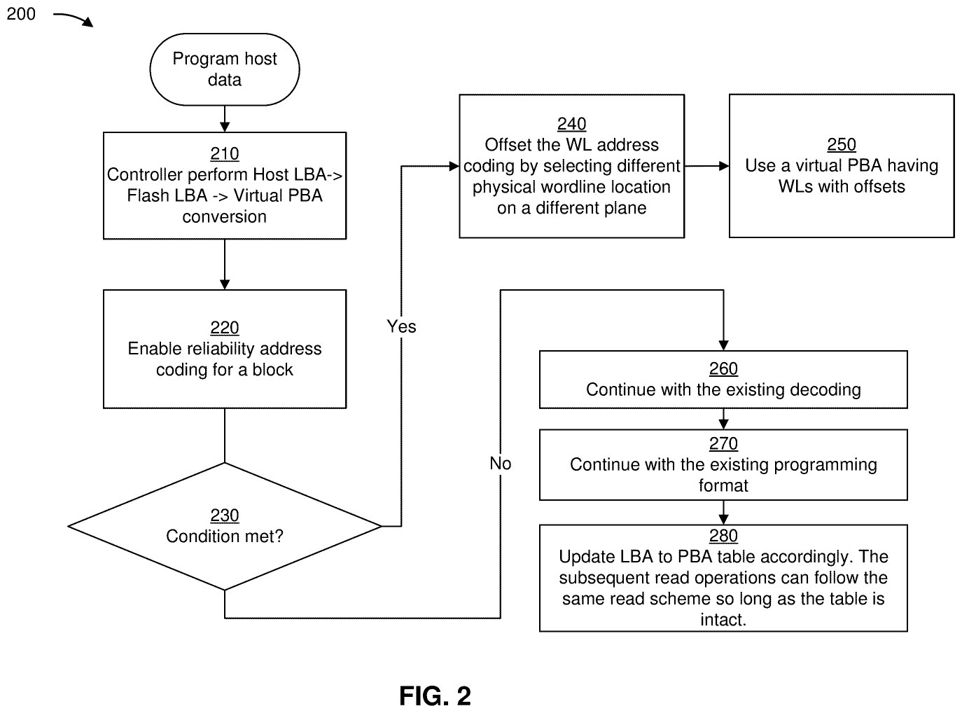

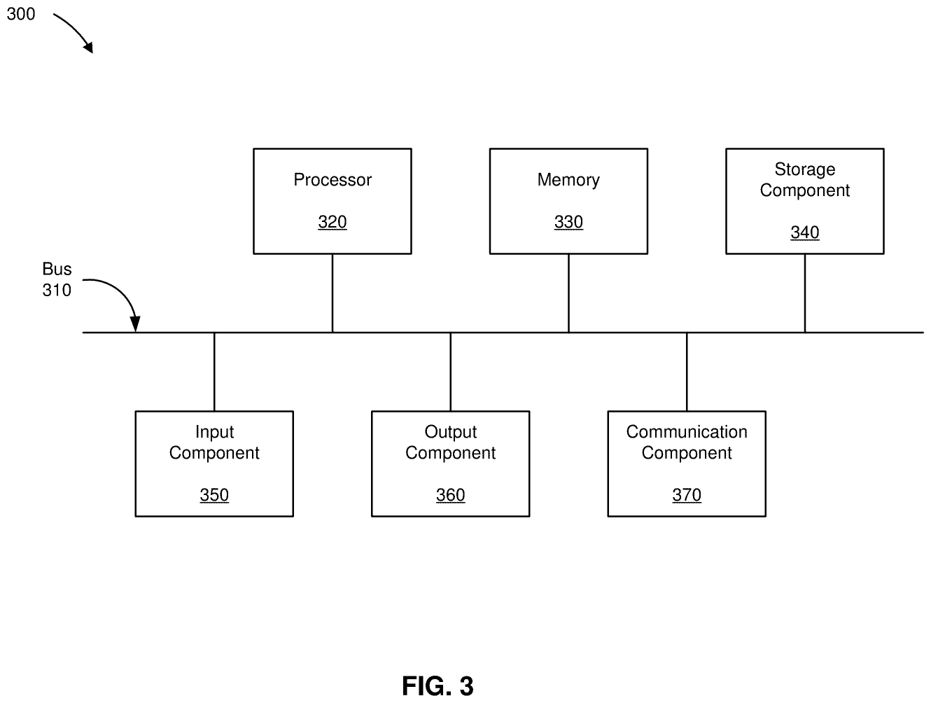

FIG. 2 is a diagram of an example process 200 associated with using multi-plane word lines. In some implementations, one or more process blocks of FIG. 2 may be performed by a controller (e.g., a NAND controller). In some implementations, one or more process blocks of FIG. 2 may be performed by another device or a group of devices separate from or including the controller. Additionally, or alternatively, one or more process blocks of FIG. 2 may be performed by one or more components of device 300 shown in FIG. 3, such as processor 320, memory 330, storage component 340, input component 350, output component 360, and/or communication component 370.

As shown in FIG. 2, a storage device may program host data. For example, the storage device may receive a command from a host device to write data on the storage device via a set of planes having a set of word lines. The word lines may be organized into multi-plane word lines that include word lines from different planes.

As shown in FIG. 2, at block 210, a controller of the storage device may perform a host logical block addressing (LBA) to flash LBA to virtual physical block address (PBA) conversion. In this way, the controller may convert an index indicated by the host (e.g., indicating a location of data) to an index of a physical location of the data as stored on the storage device.

As shown in FIG. 2, at block 220, the controller may enable reliability address coding for a block. For example, the controller may enable reliability address coding based at least in part on one or more metrics associated with an expected error rate of data stored on the block. In some aspects, the expected error rate may be based at least in part on a program/erase cycle count, among other examples.

As shown in FIG. 2, at block 230, the controller may identify whether a condition is met. For example, the controller may determine whether the one or more metrics satisfy a threshold. If the condition is met, at block 240, the controller may offset the word line address coding by selecting different physical word line locations on different planes (e.g., NAND planes). In some aspects, the controller may offset the word line on the same die or on different dies of the storage device (e.g., NAND dies). At block 250, the storage device may use a virtual PBA having word lines with offsets. The storage device may write data to these virtual word lines and then read data from these virtual word lines. In this way, the use of word lines with offsets (e.g., a virtual word line) may be transparent to the host device because the host device references a host LBA that the storage device converts to a multi-plane word line with offsets.

If the condition is not met, at block 260, the controller may continue with existing decoding. For example, the controller may decode data stored on a multi-plane word line that includes only word lines having a same word line index. At block 270, the controller may continue with an existing programming format. For example, the controller may program data to one or more storage media on a multi-plane word line that includes only word lines having a same word line index or another configuration of a multi-plane word line that is in use at the storage device. At block 280, the controller may update a LBA to physical block address table accordingly. Additionally, or alternatively, subsequent read operations may follow a same read scheme so long as the table is intact.

FIG. 3 is a diagram of example components of a device 300, which may correspond to one or more devices of FIGS. 1A-2, such as a storage device or the storage device. In some implementations, the controller or the host device may include one or more devices 300 and one or more components of device 300. As shown in FIG. 3, device 300 may include a bus 310, a processor 320, a memory 330, a storage component 340, an input component 350, an output component 360, and a communication component 370.

Bus 310 includes a component that enables wired or wireless communication among the components of device 300. Processor 320 includes a central processing unit, a graphics processing unit, a microprocessor, a controller, a microcontroller, a digital signal processor, a field-programmable gate array, an application-specific integrated circuit, or another type of processing component. Processor 320 is implemented in hardware, firmware, or a combination of hardware and software. In some implementations, processor 320 includes one or more processors capable of being programmed to perform a function. Memory 330 includes a random access memory, a read only memory, or another type of memory (e.g., a flash memory, a magnetic memory, or an optical memory). In some implementations, memory 330 may include an ECC engine or an LDPC engine, described above. In this case, memory 330 may be an ecosystem of its own with its own processor(s), controller, LDPC engine, and storage media such as NAND.

Storage component 340 (e.g., storage device 105) stores information or software related to the operation of device 300. For example, storage component 340 may include a hard disk drive, a magnetic disk drive, an optical disk drive, a solid state disk drive, a compact disc, a digital versatile disc, or another type of non-transitory computer-readable medium. In some implementations, storage component 340 may include an ECC engine or an LDPC engine, described above. In this case, storage component 340 may be an ecosystem of its own with its own processor(s), controller, LDPC engine, and storage media such as NAND.

Input component 350 enables device 300 to receive input, such as user input or sensed inputs. For example, input component 350 may include a touch screen, a keyboard, a keypad, a mouse, a button, a microphone, a switch, a sensor, a global positioning system component, an accelerometer, a gyroscope, or an actuator. Output component 360 enables device 300 to provide output, such as via a display, a speaker, or one or more light-emitting diodes. Communication component 370 enables device 300 to communicate with other devices, such as via a wired connection or a wireless connection. For example, communication component 370 may include a receiver, a transmitter, a transceiver, a modem, a network interface card, or an antenna.

Device 300 may perform one or more processes described herein. For example, a non-transitory computer-readable medium (e.g., memory 330 or storage component 340) may store a set of instructions (e.g., one or more instructions, code, software code, or program code) for execution by processor 320. Processor 320 may execute the set of instructions to perform one or more processes described herein. In some implementations, execution of the set of instructions, by one or more processors 320, causes the one or more processors 320 or the device 300 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 3 are provided as an example. Device 300 may include additional components, fewer components, different components, or differently arranged components than those shown in FIG. 3. Additionally, or alternatively, a set of components (e.g., one or more components) of device 300 may perform one or more functions described as being performed by another set of components of device 300.

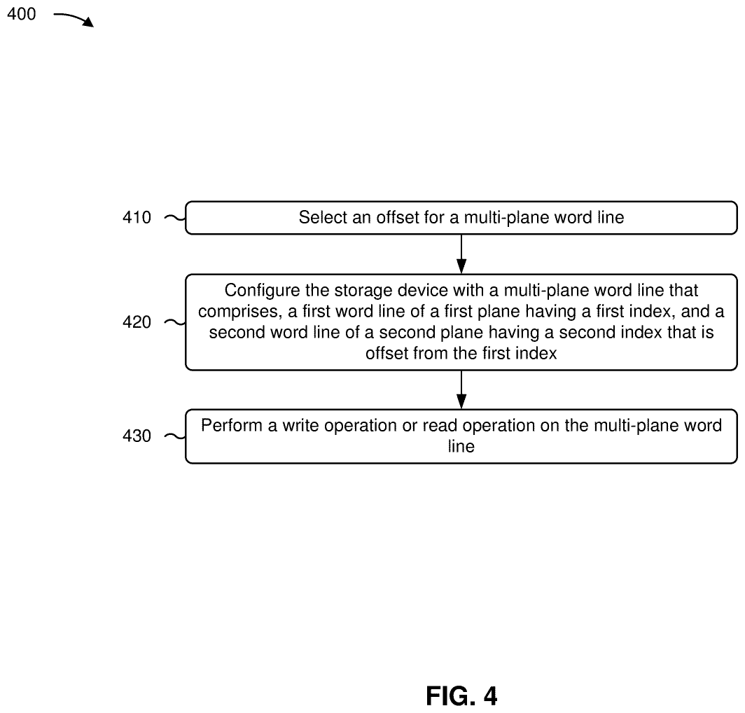

FIG. 4 is a flowchart of an example process 400 associated with using multi-plane word lines. In some implementations, one or more process blocks of FIG. 4 may be performed by a controller (e.g., a NAND controller). In some implementations, one or more process blocks of FIG. 4 may be performed by another device or a group of devices separate from or including the controller. Additionally, or alternatively, one or more process blocks of FIG. 4 may be performed by one or more components of device 300, such as processor 320, memory 330, storage component 340, input component 350, output component 360, and/or communication component 370.

As further shown in FIG. 4, process 400 may include selecting an offset for a multi-plane word line (block 410). For example, the controller or a storage medium of the storage device selects an offset for a multi-plane word line, as described above.

As shown in FIG. 4, process 400 may include configuring the storage device with a multi-plane word line that comprises: a first word line of a first plane having a first index, and a second word line of a second plane having a second index that is offset from the first index (block 420). For example, the controller may configure the storage device with a multi-plane word line that comprises: a first word line of a first plane having a first index, and a second word line of a second plane having a second index that is offset from the first index, as described above.

As further shown in FIG. 4, process 400 may include performing a write operation or read operation on the multi-plane word line (block 430). For example, the controller may perform a write operation or read operation on the multi-plane word line, as described above.

Process 400 may include additional implementations, such as any single implementation or any combination of implementations described below and/or in connection with one or more other processes described elsewhere herein.

In some implementations, the multi-plane word line comprises a third word line of a third plane having a third index, and wherein the third index is offset from the second index by a magnitude that is equal to the offset from the second index to the first index.

In some implementations, the first index and the second index are associated with a range of indices associated with tiers of word lines, wherein the first index has a first value and is associated with a first tier of word lines, wherein the second index has a second value and is associated with a second tier of word lines, and wherein the second value is equal to the first value.

In some implementations, the first index and the second index are associated with a range of indices associated with tiers of word lines, wherein the first index has a first value and is associated with a first tier of word lines, wherein the second index has a second value and is associated with a second tier of word lines, and wherein the second value is equal to difference between a highest value of the range of indices and the first value.

In some implementations, the first index and the second index are associated with a range of indices associated with tiers of word lines, wherein the first index has a first value and is associated with a first tier of word lines that is counted in a first direction, wherein the second index has a second value and is associated with a second tier of word lines that is counted in a second direction that is opposite the first direction.

In some implementations, the first index and the second index are associated with a range of indices associated with tiers of word lines, and wherein the offset between the first word line index and the second word line index is equal to a length of the tiers of word lines.

In some implementations, an additional multi-plane word line of the plurality of multi-plane word lines comprises a third word line of the first plane having a third index, and a fourth word line of the second plane having a fourth index that is offset from the third index by an amount that is different from offset from the first index to the second index.

In some implementations, performing the read operation comprises applying an error correction operation to correct one or more word lines of the multi-plane word line.

In some implementations, the offset between the first index and the second index is associated with a first die of the storage device, and wherein an additional offset between the first index and the second index is associated with a second die of the storage device.

In some implementations, alone or in combination with one or more of the first through eighth implementations, configuring the storage device with the multi-plane word line where the second index is offset from the first index is based at least in part on satisfaction of an error rate of a read operation associated with the multi-plane word line where the second index is not offset from the first index.

In some implementations, process 400 includes selecting a size of the offset between the second word line and the first word line based at least in part on satisfaction of an error rate of a read operation associated with the multi-plane word line.

In some implementations, process 400 includes enabling reliability address coding based at least in part on one or more metrics associated with an expected error rate of data stored on the block; and identifying whether a condition is met. In some implementations, identifying whether the condition is met comprises determining whether the one or more metrics satisfy a threshold; and selecting different physical word line locations, associated with the offset, on different planes. In some aspects, the reliability address coding comprises coding associated with production screening statistical data to check if simultaneous failure across a same word line index on different planes has a likelihood that satisfies a threshold.

In some implementations, the write operation may be performed with the multi-plane word line with data before the read operation to read data. The newly formed multi-plane worldline's address coding has been remembered by the system to carry out a write operation and a read operation on the multi-plane word line.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

In some implementations, a method performed by a controller of a storage device includes configuring the storage device with a multi-plane word line that comprises a first word line of a first plane having a first index, and a second word line of a second plane having a second index that is offset from the first index. The method also includes performing a write operation or read operation on the multi-plane word line.

In some implementations, a system comprising: a controller, of a non-volatile memory device, arranged to configure a storage device with a multi-plane word line that comprises a first word line of a first plane having a first index, and a second word line of a second plane having a second index that is offset from the first index. The controller may also be configured to perform a write operation or read operation on the multi-plane word line.

In some implementations, a computer program product comprises one or more computer readable storage media, and program instructions collectively stored on the one or more computer readable storage media. The program instructions include program instructions to configure a storage device with a multi-plane word line that comprises a first word line of a first plane having a first index, and a second word line of a second plane having a second index that is offset from the first index. The program instructions also include program instructions to perform a write operation or read operation on the multi-plane word line.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code-it being understood that software and hardware can be used to implement the systems or methods based at least in part on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based at least in part on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method performed by a controller of a storage device, the method comprising:
configuring the storage device with a multi-plane word line that comprises:
a first word line of a first plane having a first index, and
a second word line of a second plane having a second index that is offset from the first index; and
performing a write operation or read operation on the multi-plane word line.

2. The method of claim 1, wherein the multi-plane word line comprises a third word line of a third plane having a third index, and
wherein the third index is offset from the second index by a magnitude that is equal to a magnitude of the offset from the second index to the first index.

3. The method of claim 1, wherein the first index and the second index are associated with a range of indices associated with tiers of word lines,
wherein the first index has a first value and is associated with a first tier of word lines,
wherein the second index has a second value and is associated with a second tier of word lines, and
wherein the second value is equal to the first value.

4. The method of claim 1, wherein the first index and the second index are associated with a range of indices associated with tiers of word lines,
wherein the first index has a first value and is associated with a first tier of word lines,
wherein the second index has a second value and is associated with a second tier of word lines, and
wherein the second value is equal to a difference between a highest value of the range of indices and the first value.

5. The method of claim 1, wherein the first index and the second index are associated with a range of indices associated with tiers of word lines, and
wherein the offset between the first word line index and the second word line index is equal to a length of the tiers of word lines.

6. The method of claim 1, wherein an additional multi-plane word line of the plurality of multi-plane word lines comprises:
a third word line of the first plane having a third index, and
a fourth word line of the second plane having a fourth index that is offset from the third index by an amount that is different from an offset from the first index to the second index.

7. The method of claim 1, wherein performing the read operation comprises:
applying an error correction operation to correct one or more word lines of the multi-plane word line.

8. The method of claim 1, wherein the offset between the first index and the second index is associated with a first die of the storage device, and
wherein an additional offset between the first index and the second index is associated with a second die of the storage device.

9. The method of claim 1, wherein configuring the storage device with the multi-plane word line where the second index is offset from the first index is based at least in part on:
satisfaction of an error rate of a read operation associated with the multi-plane word line where the second index is not offset from the first index.

10. The method of claim 1, comprising selecting a size of the offset between the second word line and the first word line based at least in part on:
satisfaction of an error rate of a read operation associated with the multi-plane word line.

11. A system comprising:
a controller, of a non-volatile memory device, to:
configure a storage device with a multi-plane word line that comprises:
a first word line of a first plane having a first index, and
a second word line of a second plane having a second index that is offset from the first index; and
perform a write operation on the multi-plane word line.

12. The system of claim 11, wherein the multi-plane word line comprises a third word line at one of the first index or the second index.

13. The system of claim 11, wherein the first index and the second index are associated with a range of indices associated with tiers of word lines,
wherein the first index has a first value within a first tier of word lines,
wherein the second index has the first value within a second tier of word lines.

14. The system of claim 13, wherein the first index is counted in a first direction within the first tier of word lines, and
wherein the first index is counted in a second direction that is opposite the first direction within the second tier of word lines.

15. The system of claim 11, wherein the multi-plane word line comprises word lines within multiple storage media.

16. A computer program product comprising:
one or more computer readable storage media, and program instructions collectively stored on the one or more computer readable storage media, the program instructions comprising:
program instructions to configure a storage device with a multi-plane word line that comprises:
a first word line of a first plane having a first index, and
a second word line of a second plane having a second index that is offset from the first index; and
program instructions to perform a write operation or a read operation on the multi-plane word line.

17. The computer program product of claim 16, wherein the multi-plane word line comprises a third word line of a third plane having a third index, and
wherein the third index is offset from the second index by a magnitude that is different from the offset from the second index to the first index.

18. The computer program product of claim 16, wherein the program instructions comprise program instructions to select a size of the offset between the second word line and the first word line based at least in part on:
satisfaction of an error rate of a read operation associated with one or more planes associated with the multi-plane word line.

19. The computer program product of claim 16, wherein the program instructions comprise program instructions to:
enable reliability address coding based at least in part on one or more metrics associated with an expected error rate of data stored on the block; and
identify whether a condition is met.

20. The computer program product of claim 19, wherein, to identify whether the condition is met, the program instructions comprise program instructions to:
determine whether the one or more metrics satisfy a threshold; and
select different physical word line locations, associated with the offset, on different planes.

21. The computer program product of claim 19, wherein, the reliability address coding comprises:
coding associated with production screening statistical data to check if simultaneous failure across a same word line index on different planes has a likelihood that satisfies a threshold.

22. The computer program product of claim 16, wherein the program instructions comprise:
program instructions to perform the write operation prior to performing the read operation.
